(19) United States
(12) Patent Application Publication
(10) Pub. No.: US 2007/0045722 A1
(43) Pub. Date: Mar. 1, 2007

(54) Non-volatile memory and fabrication thereof

(76) Inventor: Tzyh-Cheang Lee, Hsinchu City (TW)

Correspondence Address: J C PATENTS, INC., 4 VENTURE, SUITE 250, IRVINE, CA, 92618, US

(21) Appl. No.: 11/218,090

(22) Filed: Aug. 31, 2005

(51) Int. Cl. H01L 29/94

(52) U.S. Cl. 257/330

(57) ABSTRACT

A non-volatile memory cell is described, including a semiconductor body of a first conductivity type, a trapping layer, a gate, and a first to a third doped regions of a second conductivity type. The semiconductor body has a trench thereon, the trapping layer is disposed on the surface of the trench, and the gate is disposed in the trench. The first doped region is located in the semiconductor body under the trench, and the second and third doped regions are located in the semiconductor body at two sides of the trench. A non-volatile memory array based on the memory cell, a method for fabricating the memory cell and a method for fabricating the non-volatile memory array are also described.

### BACKGROUND OF THE INVENTION

1. Field of the Invention

The present invention relates to a semiconductor memory device and a method for fabricating the same. More particularly, the present invention relates to a non-volatile memory cell, a non-volatile memory array based on the memory cell, a method for fabricating the non-volatile memory cell and, a method for fabricating the non-volatile memory array. Description of the Related Art

Conventionally, an erasable programmable non-volatile memory cell includes a stacked structure constituted of a tunneling layer, a poly-Si floating gate, an inter-gate dielectric layer and a control gate, wherein the floating gate serves as a storage site into which electrons are injected. Since the floating gate is made from a conductor, each memory cell can save only one bit.

To increase the storage capacity of non-volatile memory, some trapping-type non-volatile memory devices, such as, nitride read-only memory (NROM), are recently developed. In each memory cell of such a memory device, an insulative trapping layer is disposed between the substrate and the control gate in replacement of the floating gate. Since the trapping layer is insulative, two bits can be saved in two regions of the trapping layer near the source and drain regions by, for example, controlling the direction of the channel current.

Accordingly, as compared with the conventional non-volatile memory, the trapping-type non-volatile memory of the prior art has doubled storage capacity. However., there is always a desire to increase the storage capacity of non-volatile memory, i.e., to increase the number of bits that one memory cell can stores.

### SUMMARY OF THE INVENTION

Accordingly, one object of this invention is to provide a. non-volatile memory cell rapable of storing at least four bits of data.

Another object of this invention is to provide a non-volatile memory array based on the non-volatile memory cell of this invention.

Still another object of this invention is to provide a method for fabricating the non-volatile memory cell of this invention.

Yet another object of this invention is to provide a method for fabricating the non-volatile memory array of this invention.

The non-volatile memory cell of this invention includes a semiconductor body of a first conductivity type, a trapping layer, a gate, and a first, a second and a third doped regions of a second conductivity type. The semiconductor body has a trench thereon, and the trapping layer is disposed on the surface of the trench. The gate is disposed in the trench, separated from the semiconductor body by the trapping layer. The first doped region is located in the semiconductor body under the trench, and the second and third doped regions are located in the semiconductor body at two sides of the trench.

In the non-volatile memory cell of this invention, the semiconductor body may be a semiconductor substrate having the trench and all doped regions therein, or a composite of a semiconductor substrate having the first doped region therein and a semiconductor layer having the trench and the second and third doped regions therein.

The non-volatile memory array of this invention is based on the above non-volatile memory cell. Specifically, in the memory array, the semiconductor body has multiple trenches thereon orientated in a column direction, and the trapping layer is disposed on the surface of each trench. The semiconductor body under each trench has a first buried bit line therein, and the semiconductor body between two trenches has a second buried bit line therein. The trenches is disposed with multiple gates therein that are arranged in rows and columns, while the gates in the same row are electrically connected to a word line.

Similarly, in the non-volatile memory array of this invention, the semiconductor body may be a semiconductor substrate having the trenches and all buried bit lines therein, or a composite of a semiconductor substrate having the first buried bit lines therein and a semiconductor layer having the trenches and the second and third buried bit lines therein.

The method for fabricating a non-volatile memory cell of this invention is described as follows. A semiconductor substrate of a first conductivity type is provided, and a first doped region of a second conductivity type is formed in the substrate. A semiconductor layer is formed on the substrate, including a lower portion of the first conductivity type and an upper portion of the second conductivity type on the lower portion. The resulting semiconductor body may alternatively be made from a semiconductor substrate of the first conductivity type with two implantation steps of the second conductivity type only, wherein one implantation step forms a first doped region away from the surface layer of the substrate and the other forms a doped layer in the surface layer of the substrate. Thereafter, a trench is formed in the semiconductor layer (or in the semiconductor substrate in the alternative method) over the first doped region, so that the upper portion of the semiconductor layer (or the doped layer in the alternative method) is divided into a second and a third doped regions. A trapping layer is then formed on the surface of the trench, and a gate is formed in the trench.

The method for fabricating a non-volatile memory array of this invention is based on the above memory cell process. Specifically, before the semiconductor layer is formed, multiple first buried bit lines are formed in the substrate in a column direction. After the semiconductor layer is formed, multiple trenches are formed in the column direction, wherein each trench is located over one first buried bit line so that the upper portion of the semiconductor layer is divided into multiple second buried bit lines. The trapping layer is then formed on the substrate. Then, multiple gates and word lines are formed in the trenches and over the semiconductor layer, respectively, wherein the gates are arranged in rows and columns, and each word line is orientated in the row direction electrically connecting with the gates in one row.

Since the gate of the non-volatile memory cell of this invention is formed in a trench, two channels are defined in the semiconductor layer at two sidewalls of the gate. By altering the current direction in each channel, two bits can be stored in the trapping layer at each sidewall of the gate, as mentioned above. Consequently, totally four bits of data can be stored in one memory cell, and the storage capacity of the non-volatile memory device is significantly increased.

It is to be understood that both the foregoing general description and the following detailed description are exemplary, and are intended to provide further explanation of the invention as claimed.

### BRIEF DESCRIPTION OF THE DRAWINGS

FIGS. 1A/1B, 2, 3 and 4A/4B illustrate a process flow of fabricating a non-volatile memory array/cell according to a preferred embodiment of this invention, wherein FIG. 1A/4A is the cross-sectional view of FIG. 1B/4B along line I-I′/IV-IV′.

FIGS. 4A and 4B also show the structure of the non-volatile memory array/cell according to the preferred embodiment of this invention.

### DESCRIPTION OF THE PREFERRED EMBODIMENTS

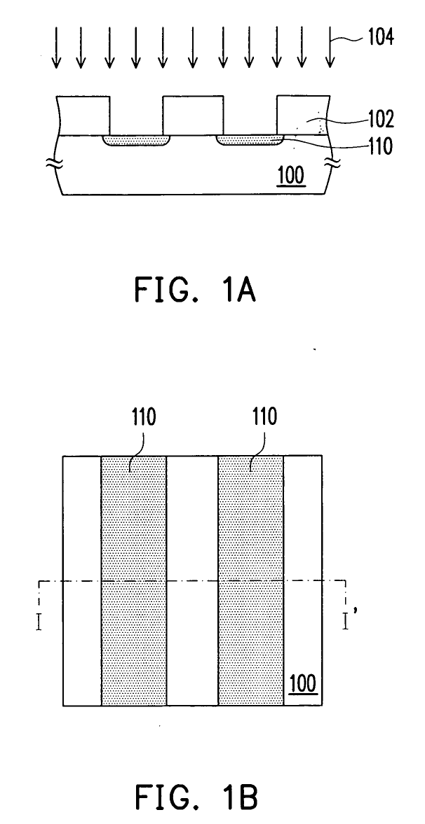

Referring to FIGS. 1A and 1B, FIG. 1A is the cross-sectional view of FIG. 1B along line I-I′. At first, a semiconductor substrate 100 of the first conductivity type is provided, which may be a P-type single-crystal silicon substrate. A patterned mask layer 102 with multiple linear patterns (not shown) is then formed on the substrate 100, and implantation 104 of the second conductivity type is performed to form multiple buried bit lines 110 in the substrate 100. The buried bit lines 110 are orientated in a column direction in FIG. 1B, and the conductivity type thereof is N-type when that of the substrate 100 is P-type.

Referring to FIG. 2, a semiconductor layer 115 is formed on the substrate 100. The semiconductor layer 115 includes a lower portion 120 of the first conductivity type and an upper portion 130 of the second conductivity type on the lower portion 120. Such a semiconductor layer 115 can be formed by, for example, firstly forming a P-doped semiconductor film (115) on the substrate 100 and then performing a doping process to convert the conductivity type of the upper portion 130 of the semiconductor film (115) to N-type. The semiconductor film (115) can be formed using an epitaxial method with in-situ doping. That is, the semiconductor layer 115 can be an epitaxial layer.

In another example, a P-type semiconductor film 120 and an N-type semiconductor film 130 are sequentially formed on the substrate 100, thereby constituting the semiconductor layer 115. Similarly, each semiconductor film 120 or 130 can be formed using an epitaxial method with in-situ doping of corresponding conductivity type. That is, the semiconductor layer 115 may be constituted of a P-type epitaxial layer 120 and an N-type epitaxial layer 130 on the P-type epitaxial layer 120.

Alternatively, the resulting semiconductor body as formed above, which includes a semiconductor substrate 100 with the buried bit lines 110 therein and the semiconductor layer 115 with the doped upper portion 130, may alternatively be made from a semiconductor substrate (equivalent to 100+115) with two implantation steps only. In the alternative method, one implantation step uses high-energy ions to form the buried bit lines 110 far away from the surface layer of the substrate (100+115), and the other implantation step forms a doped layer (equivalent to 130) in the surface layer of the substrate (100+115). Since the subsequent steps for such a semiconductor substrate in the alternative method are similar to those for the composite 110+115 in the illustrated method, they will not be described repeatedly.

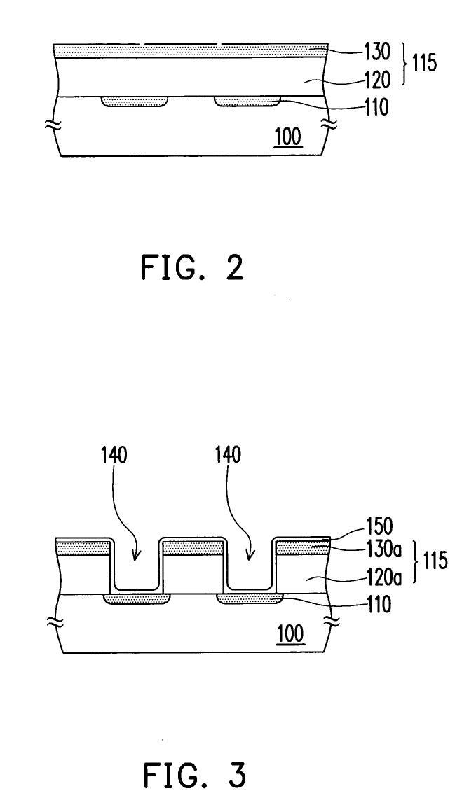

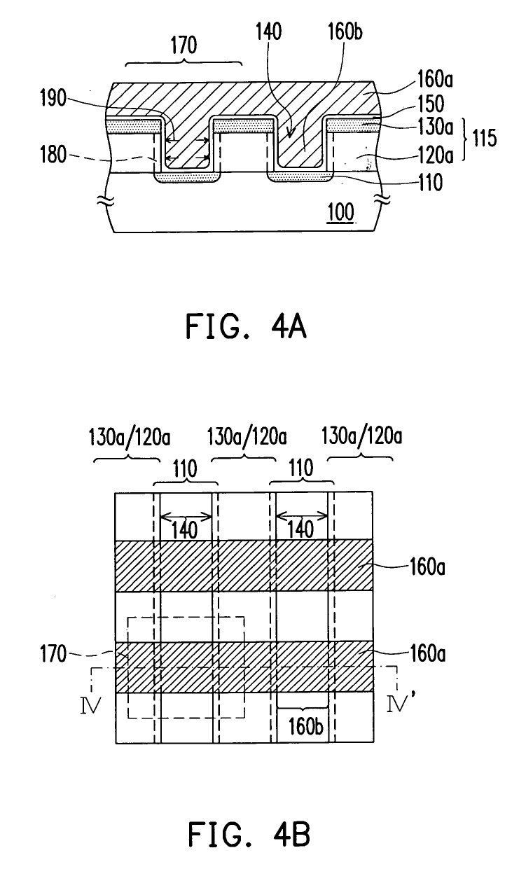

Referring to FIG. 3, after the semiconductor layer 115 is formed, multiple trenches 140 are formed in the semiconductor layer 115 in the same orientation of the buried bit lines 110 (see FIG. 4B). Each trench 140 is located over one buried bit line 110, so that the upper portion 130 of the semiconductor layer 115 is divided into multiple buried bit lines 130a. Then, a substantially conformal trapping layer 150 is formed on the substrate 100. The trapping layer 150 is, for example, a SiO/SiN/SiO (ONO) composite layer, an insulating layer containing separate conductor particles, or any other insulating layer capable of capturing electrons.

Referring to FIGS. 4A and 4B, FIG. 4A is the cross-sectional view of FIG. 4B along line IV-IV′. After the trapping layer 150 is formed, multiple word lines 160a and gates 160b are formed over the semiconductor layer 100. The gates 160b are formed in the trenches 140 and arranged in rows and columns. The word lines 160a cross over the buried bit lines 130a, while each word line 160a electrically connect with the gates 160b in one row. The word lines 160a and gates 160b can be defined from the same conductive layer (not shown). In such a case, for example, a conductive layer is deposited, planarized, and then patterned perpendicular to the buried bit lines 110 and 130a to form the word lines 160a and gates 160b successively. In addition, the conductive layer/word lines 160a/gates 160b may include a material selected from the group consisting of doped polysilicon, metal silicide, metal and combinations thereof.

FIGS. 4A and 4B also show the structure of the non-volatile memory array/cell according to the preferred embodiment of this invention. The non-volatile memory cell-is labeled with “170”, and the region of unit memory cell is also shown in FIG. 4B. The structure of the non-volatile memory cell/array can be fully understood according to the above descriptions. Moreover, the method for forming a non-volatile memory cell according to the preferred embodiment of this invention can also be realized by referring to FIGS. 1A, 2-3 and 4A and the related descriptions.

Referring to FIG. 4A, since the gate 160b of a non-volatile memory cell 170 of this invention is formed in a trench 140, two channels 180 are defined in the lower part 120a of the semiconductor layer 115 at two sidewalls of the gate 160b. By altering the current direction in each channel 180, two bits can be stored in the trapping layer 150 at each sidewall of the gate 160b, as indicated by the arrows 190. Consequently, totally four bits of data can be stored in one memory cell 170, and the storage capacity of the non-volatile memory device is significantly increased.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

What is claimed is:

1. A non-volatile memory cell, comprising:
a semiconductor body of a first conductivity type, having a trench thereon;
a trapping layer on a surface of the trench;
a gate in the trench;
a first doped region of a second conductivity type in the semiconductor body under the trench; and
a second and a third doped regions of the second conductivity type in the semiconductor body at two sides of the trench.

2. The non-volatile memory cell of claim 1, wherein the semiconductor body comprises a semiconductor substrate having the trench and all doped regions therein.

3. The non-volatile memory cell of claim 1, wherein the semiconductor body comprises:
a semiconductor substrate having the first doped region therein; and
a semiconductor layer on the semiconductor substrate, having the trench and the second and third doped regions therein.

4. The non-volatile memory cell of claim 3, wherein the semiconductor layer comprises an epitaxial layer.

5. The non-volatile memory cell of claim 3, wherein the semiconductor layer comprises:
a first epitaxial layer of the first conductivity; and
a second epitaxial layer of the second conductivity on the first epitaxial layer, serving as the second and third doped regions.

6. The non-volatile memory cell of claim 1, wherein the trapping layer comprises an ONO composite layer, or an insulating layer containing separate conductor particles.

7. The non-volatile memory cell of claim 1, wherein the gate comprises a material selected from the group consisting of doped polysilicon, metal silicide, metal and combinations thereof.

8. The non-volatile memory cell of claim 1, wherein the first conductivity type is P-type and the second conductivity type is N-type.

9. A non-volatile memory array, comprising:
a semiconductor body of a first conductivity type, having a plurality of trenches thereon orientated in a column direction;
a plurality of first buried bit lines of a second conductivity type, wherein each first buried bit line is located in the semiconductor body under a corresponding trench;
a plurality of second buried bit lines of the second conductivity type, located in the semiconductor body between the trenches;
a trapping layer on a surface of each trench;
a plurality of gate in the trenches, arranged in rows and columns and separated from the semiconductor body by the trapping layer; and
a plurality of word lines in a row direction, wherein each word line is electrically connected with the gates in one row.

10. The non-volatile memory array of claim 9, wherein the semiconductor body comprises a semiconductor substrate having the trenches and all buried bit lines therein.

11. The non-volatile memory array of claim 9, wherein the semiconductor body comprises:
a semiconductor substrate having the first buried bit lines therein; and
a semiconductor layer on the semiconductor substrate, having the trenches and the second buried bit lines therein.

12. The non-volatile memory array of claim 11, wherein the semiconductor layer comprises an epitaxial layer.

13. The non-volatile memory array of claim 11, wherein the semiconductor layer comprises:
a first epitaxial layer of the first conductivity; and
a second epitaxial layer of the second conductivity type on the first epitaxial layer, serving as the second buried bit lines.

14. The non-volatile memory array of claim 9, wherein the trapping layer comprises an ONO composite layer, or an insulating layer containing separate conductor particles.

15. The non-volatile memory array of claim 9, wherein each word line is contiguous with the gates in the corresponding row.

16. The non-volatile memory array of claim 15, wherein the word line and the gates comprise a material selected from the group consisting of doped polysilicon, metal silicide, metal and combinations thereof.

17. The non-volatile memory array of claim 9, wherein the first conductivity type is P-type and the second conductivity type is N-type.

18. A method for fabricating a non-volatile memory cell, comprising:
providing a semiconductor substrate of a first conductivity type;
forming a first doped region of a second conductivity type in the substrate,
forming a semiconductor layer on the substrate, the semiconductor layer including a lower portion of the first conductivity type and an upper portion of the second conductivity type on the lower portion;
forming a trench in the semiconductor layer over the first doped region, so that the upper portion of the semiconductor layer is divided into a second and a third doped regions;
forming a trapping layer on a surface of the trench; and
forming a gate in the trench.

19. The method of claim 18, wherein the step of forming the semiconductor layer comprises:
forming a semiconductor film of the first conductivity type on the substrate; and
doping an upper portion of the semiconductor film to the second conductivity type.

20. The method of claim 19, wherein the step of forming the semiconductor film of the first conductivity type comprises an epitaxy process.

21. The method of claim 18, wherein the step of forming the semiconductor layer comprises:
forming a first semiconductor film of the first conductivity type on the substrate; and
forming a second semiconductor film of the second conductivity type on the first semiconductor film.

22. The method of claim 21, wherein the step of forming the first semiconductor film and the step of forming the second semiconductor film each comprises an epitaxy process.

23. The method of claim 18, wherein the trapping layer comprises an ONO composite layer, or an insulating layer containing separate conductor particles.

24. The method of claim 18, wherein the gate comprises a material selected from the group consisting of doped polysilicon, metal silicide, metal and combinations thereof.

25. The method of claim 18, wherein the first conductivity type is P-type and the second conductivity type is N-type.

26. A method for fabricating a non-volatile memory array, comprising:
providing a semiconductor substrate of a first conductivity type;
forming a plurality of first buried bit lines of a second conductivity type in the substrate, the first buried bit lines being orientated in a column direction;
forming a semiconductor layer on the substrate, the semiconductor layer including a lower portion of the first conductivity type and an upper portion of the second conductivity type on the lower portion;
forming a plurality of trenches in the semiconductor layer, wherein each trench is located over one first buried bit line so that the upper portion of the semiconductor layer is divided into a plurality of second buried bit lines;
forming a trapping layer over the substrate; and
forming a plurality of gates in the trenches and a plurality of word lines over the semiconductor layer, wherein the gates are arranged in rows and columns, and each word line is orientated in a row direction electrically connecting with the gates in one row.

27. The method of claim 26, wherein the step of forming the semiconductor layer comprises:
forming a semiconductor film of the first conductivity type on the substrate; and
doping an upper portion of the semiconductor film to the second conductivity type.

28. The method of claim 27, wherein the step of forming the semiconductor film of the first conductivity type comprises an epitaxy process.

29. The method of claim 26, wherein the step of forming the semiconductor layer comprises:
forming a first semiconductor film of the first conductivity type on the substrate; and
forming a second semiconductor film of the second conductivity type on the first semiconductor film.

30. The method of claim 29, wherein the step of forming the first semiconductor film and the step of forming the second semiconductor film each comprises an epitaxy process.

31. The method of claim 26, wherein the trapping layer comprises an ONO composite layer, or an insulating layer containing separate conductor particles.

32. The method of claim 26, wherein each word line is contiguous with the gates in the corresponding row.

33. The method of claim 26, wherein the word line and the gates comprise a material selected from the group consisting of doped polysilicon, metal silicide, metal and combinations thereof.

34. The method of claim 26, wherein the first conductivity type is P-type and the second conductivity type is N-type.

35. A method for fabricating a non-volatile memory cell, comprising:
providing a semiconductor substrate of a first conductivity type;
forming a first doped region of a second conductivity type in the substrate away from a surface layer of the substrate;
forming a doped layer of the second conductivity type in the surface layer of the substrate;
forming a trench in the substrate over the first doped region, so that the doped layer is divided into a second and a third doped regions;
forming a trapping layer on a surface of the trench; and
forming a gate in the trench.

36. The method of claim 35, wherein the trapping layer comprises an ONO composite layer, or an insulating layer containing separate conductor particles.

37. The method of claim 35, wherein the gate comprises a material selected from the group consisting of doped polysilicon, metal silicide, metal and combinations thereof.

38. The method of claim 35, wherein the first conductivity type is P-type and the second conductivity type is N-type.

39. A method for fabricating a non-volatile memory array, comprising:
providing a semiconductor substrate of a first conductivity type;
forming a plurality of first buried bit lines of a second conductivity type in the substrate, the first buried bit lines being orientated in a column direction and being away from a surface layer of the substrate;
forming a doped layer of the second conductivity type in the surface layer of the substrate;
forming a plurality of trenches in the substrate, wherein each trench is located over one first buried bit line so that the doped layer is divided into a plurality of second buried bit lines;
forming a trapping layer over the substrate; and
forming a plurality of gates in the trenches and a plurality of word lines over the semiconductor layer, wherein the gates are arranged in rows and columns, and each word line is orientated in a row direction electrically connecting with the gates in one row.

40. The method of claim 39, wherein the trapping layer comprises an ONO composite layer, or an insulating layer containing separate conductor particles.

41. The method of claim 39, wherein each word line is contiguous with the gates in the corresponding row.

42. The method of claim 39, wherein the word line and the gates comprise a material selected from the group consisting of doped polysilicon, metal silicide, metal and combinations thereof.

43. The method of claim 39, wherein the first conductivity type is P-type and the second conductivity type is N-type.
